(19) United States
(12) Patent Application Publication
(10) Pub. No.: US 2026/0293522 A1
(43) Pub. Date: Sep. 24, 2026

(54) ELECTRONIC EQUIPMENT COMPRISING AT LEAST ONE THERMOELECTRIC MODULE, CORRESPONDING ELECTRONIC SYSTEM

(71) Applicant: SAFRAN ELECTRONICS & DEFENSE, PARIS (FR)

(72) Inventors: Jean-Christophe RIOU, MOISSY-CRAMAYEL (FR); Nawres SRIDI-CONVERS, MOISSY-CRAMAYEL (FR); Eric BAILLY, MOISSY-CRAMAYEL (FR)

(21) Appl. No.: 19/474,587

(22) PCT Filed: Apr. 12, 2024
(86) PCT No.: PCT/EP2024/060080

§ 371 Date: Oct. 10, 2025

(30) Foreign Application Priority Data
Apr. 14, 2023 (FR) FR2303731

(51) Int. Cl. H10N 10/13

(52) U.S. Cl. CPC H10N 10/13

(57) ABSTRACT

Electronic equipment (and a corresponding electronic system) includes a supporting member and at least one component. At least one thermoelectric module is associated with the component. The module is shaped as a block including two main heat-exchange faces. The module is integrated at least partially into the supporting member such that a first of its two main faces is in contact with at least one of the faces of the component, either directly or via at least one link made of an at least thermally conductive material.

The invention relates to electronic equipment comprising at least one thermoelectric module.

The invention also relates to a system comprising such equipment.

### BACKGROUND OF THE INVENTION

Climate change is a major concern for many legislative and regulatory bodies around the world. Indeed, a wide variety of restrictions on carbon emissions have been, are being or will be adopted by various states. In particular, an ambitious standard applies both to new types of aircraft and also to those in use which require the implementation of technological solutions in order to comply with the regulations in force. Civil aviation has been mobilising for several years now to make a contribution to the fight against climate change.

Technological research efforts have already made it possible to very significantly improve the environmental performance of aircraft. The Applicant must take into account the factors impacting in all phases of design and development to obtain aeronautical components and products which are more energy-efficient, more environmentally-friendly and whose integration and use in civil aviation have moderate environmental consequences with the aim of improving the energy efficiency of aircraft.

As a result, the Applicant is constantly working to reduce its negative climatic impact by using virtuous methods and manufacturing processes and minimising greenhouse gas emissions to the minimum possible to reduce the environmental footprint of its activity.

This sustained research and development related to both new generations of aircraft engines, the lightening of aircraft, in particular, by the materials used and the lightened on-board equipment, developing the use of electrical technologies to ensure propulsion, and, essential in addition to technological advances, aeronautical biofuels.

However, aircraft, electronic equipment and systems tend to release heat, that generally requires them to be associated with large and energy-intensive cooling systems, such as fans or air conditioners.

### AIM OF THE INVENTION

An aim of the invention is to propose electronic equipment that is more environmentally-friendly.

An aim of the invention is to propose an electronic system comprising such equipment.

### SUMMARY OF THE INVENTION

For this purpose, electronic equipment comprising at least one supporting member and at least one component is provided.

According to the invention, the equipment comprises at least one that is associated with the component and that is shaped as a block comprising two main heat-exchange faces, the module being integrated at least partially into the supporting member such that a first of its two main faces is in contact with at least one of the faces of the component, either directly or via at least one link made of at least thermally conductive material, wherein the component comprises a first face associated with the thermoelectric module and a second face associated either with a second thermoelectric module or with a second supporting member, such that an assembly formed by the component, the thermoelectric module and, either the second thermoelectric module or the second supporting member, forms a stack.

Thus, by integrating a thermoelectric module into the supporting member itself, it is easier to ensure heat exchanges with the component.

Considering the fact that the heat exchanges between the component and the thermoelectric module are local, they are more efficient and faster.

The invention is therefore more environmentally-friendly. In addition, premature ageing of the associated component is limited (due, for example, to its heating if the module was not present). This improves the performance of the electronic equipment over time.

The invention is thus the result of technological research aimed at very significantly improving aircraft performance and, in this sense, contributes to reducing the environmental impact of aircraft.

In terms of the present application, it must be noted that a “thermoelectric module” is a module for implementing the Peltier effect: when the module is electrically powered, it generates a temperature difference such that one of its main faces is hot and the other is cold. Conversely, such a module also makes it possible to implement the Seebeck effect: when a temperature gradient is applied to the module, it generates an electric current. The thermoelectric module thus comprises one or more of the thermoelectric materials enabling both of the above-mentioned effects to be implemented.

In terms of the present application, the term “direct contact” between an element A and an element B is understood to mean that the element A touches the element B without an intermediate macroscopic piece C. Of course, when the element A and the element B are in direct contact, a possible layer of attaching material (for example, a layer of sintering material, in particular, silver copper sintering, or a layer of cross-linking material, for example a thermally conductive adhesive, or a layer of brazing material) may be present between the element A and the element B in order to attach the said elements together. This layer is obviously not similar to an intermediate macroscopic piece C.

The terminology, “element A associated with an element B” is understood to mean that the element A is in direct or indirect contact with the element B. When the element A is a thermoelectric module and it is “associated” with an element B, it is thus understood that the element A is in direct or indirect contact with the element B in order to allow heat exchanges between the element and the element B.

Optionally, the module is entirely arranged in the supporting member.

Optionally, the equipment comprises thermal regulation means associated with the module.

Optionally, the thermal regulation means are arranged at least partially inside of the supporting member.

Optionally, the module is in direct contact with at least one element of the thermal regulation means.

Optionally, the thermal regulation means comprise a drain made of a thermally conductive material.

Optionally, the thermal regulation means comprise a thermal reference interface, the module being in contact with said thermal reference interface, either directly or via a link made of thermally conductive material.

Optionally, the component is a first component, the equipment being configured to allow temperature regulation of a group comprising the first component and at least one second component.

Optionally, the module is a first module (7) associated with the first component, the equipment comprising a second module (17) associated with the second component.

Optionally, the supporting member is a first supporting member (2), at least one of the components being carried by a second supporting member (22) of the electronic equipment.

Optionally, the equipment comprises a third supporting member carrying the second module.

Optionally, the first module, the first component, the second component and the second module are superimposed so as to form a stack.

Optionally, the first module implements the Peltier effect and the second module implements the Seebeck effect.

Optionally, the module is a first module, the equipment comprising a second module associated with another face of the component, the first module, the component and the second module being superposed so as to form a stack.

Optionally, the equipment is a power module.

The invention also relates to an electronic system comprising equipment as described above, the electronic system being an aircraft electronic system.

Other features and advantages of the invention will become apparent on reading the following description of particular and non-limiting embodiments of the invention.

### BRIEF DESCRIPTION OF THE DRAWINGS

Reference will be made to the accompanying drawings, among which:

FIG. 1 is a cross-sectional view of electronic equipment according to a first embodiment of the invention;

FIG. 2 comprises a cross-sectional view of electronic equipment according to a second embodiment of the invention, and also a cross-sectional view associated with a zoom close-up of a part of said equipment;

FIG. 3 is a cross-sectional view of electronic equipment according to a third embodiment of the invention;

FIG. 4 is a cross-sectional view of electronic equipment according to a fourth embodiment of the invention;

FIG. 5 is a cross-sectional view of electronic equipment according to a fifth embodiment of the invention;

FIG. 6 is a cross-sectional view of electronic equipment according to a sixth embodiment of the invention;

FIG. 7 comprises a cross-sectional view of electronic equipment according to a seventh embodiment of the invention, and also a cross-sectional view associated with a zoom close-up of a part of said equipment;

FIG. 8 is a cross-sectional view of electronic equipment according to an eighth embodiment of the invention; FIG. 9 is a cross-sectional view of electronic equipment according to a ninth embodiment of the invention.

### DETAILED DESCRIPTION OF THE INVENTION

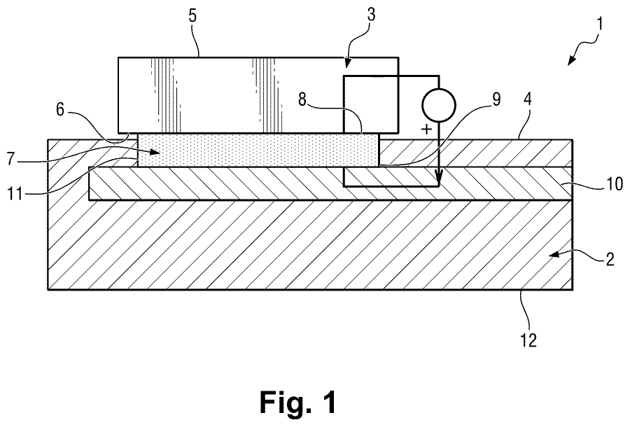

FIG. 1 shows electronic equipment 1 in a first embodiment, the equipment comprising a supporting member 2. The supporting member 2 carries at least one component 3, in this case, on its upper surface 4. In this case, the component 3 has two main faces, a first face 5 facing towards the outside of the supporting member 2 and a second face 6 facing towards the supporting member 2. The component 3 is linked to the supporting member at its second face 6.

According to the invention, the component 3 is associated with a thermoelectric module 7.

As indicated above, a thermoelectric module 7 may implement the Peltier effect: when the thermoelectric module 7 is electrically powered, it generates a temperature difference so as to have a hot zone and a cold zone. By reversing the direction of the current passing through the thermoelectric module 7, the role of said zones is reversed and the hot zone becomes the cold zone and vice-versa. TO ensure optimised heat transfer with the outside, the thermoelectric module 7 is preferably configured so as to minimise heat losses at the external interface/hot zone, on the one hand, and the external interface/cold zone, on the other hand. In particular, the thermoelectric module 7 is configured so as to minimise the thermal resistance at the outer interface/hot zone, on the one hand, and the outer interface/cold zone, on the other hand. Optionally, the component 3 is attached to the supporting member 2 via the module 7. Typically, the second face 6 of the component 3 is attached to the module 7, for example, by sintering, for example, by sintering based on silver or copper, by cross-linking, for example, a thermally conductive adhesive, or by brazing.

The module 7 is directly attached to the supporting member 2 by sintering, for example, by sintering based on silver or copper, by cross-linking, for example, a thermally conductive adhesive, or by brazing. Preferably, the material attaching the component 3 to the supporting member 2 and/or the material attaching the module 7 to the supporting member 2 is electrically conductive and/or thermally conductive.

In a manner known per se, the supporting member 2 is shaped so as to be capable of conducting an electrical current. That is how the component 3 may be electrically powered. Different options are thus known.

The component 3 may thus be electrically powered by the supporting member 2 and/or by the module 7. This power supply of the component 3 by the supporting member 2 and/or the module 7 is applicable for all of the other embodiments of the present application.

For example, the supporting member 2 is a printed circuit board: it thus comprises an electrically insulating substrate provided with one or more tracks and/or one or more pathways made of electrically conductive material allowing current to be conducted through the supporting member 2 to the component 3 and/or to the module 7.

In a first option, the supporting member 2 is shaped, on one hand, to supply power to the component 3 (without any intervention by the module 7) and, on the other hand, to supply power to the module 7. The electrical power supply of the component 3 and the module 7 by the supporting member 2 is therefore independent.

According to a second option, the supporting member 2 is configured to power the module 7 without directly powering the component 3. It is then the module 7 that transcribes the electric current into the component 3. For this purpose, the material used to attach the module 7 to the supporting member 1, on the one hand, and the component 3 to the module 7, on the other hand, is made of an electrically conductive material in order to allow the component 3 to be electrically powered by the supporting member 2 and the module 7 (by its thermoelectric nature, the module 7 makes it possible to act as an electrical conductor between the supporting member 2 and the component 3, for example, via one or more electrically conductive segments passing through it, the module 7 thus passively making it possible to power the component 3). In addition, the material used to attach the module 7 to the supporting member 1, on the one hand, and the component 3 to the module 7, on the other hand, is made of an electrically conductive material and is also thermally conductive.

The use of such a material makes it possible to limit the electrical resistance at the interfaces of the hot and cold zones of the module 7 with the outside and thus to optimize the heat exchanges with the outside. For this purpose, the intention is that the material has an electrical resistance less than or equal to one milliohms.

In a third option, the supporting member 2 is configured to power the component 3 without powering the module 7. It is then the component 3 that transcribes the electric current into the module 7. For this purpose, the material used to attach the module 7 to the supporting member 1, on the one hand, and the component 3 to the module 7, on the other hand, is made of an electrically conductive material. In addition, the material used to attach the module 7 to the supporting member 1, on the one hand, and the component 3 to the module 7, on the other hand, is made of an electrically conductive material and is also thermally conductive.

The module 7 is shaped as a block comprising two main faces for heat exchange with the outside, 8, 9. The module 7 is shaped such that both of the faces 8, 9 extend parallel to each other.

Due to its thermoelectric characteristics, when the module 7 is electrically powered, a temperature differential appears between its two main faces such that the module thus has a so-called “cold” face and a so-called “hot” face, the hot face (respectively, the cold face) being a first of the two main faces of the module (respectively, the second of the two main faces of the module) according to the flow direction of the electric current in the module 7.

It is therefore understood that to benefit from the thermoelectric characteristics of the module 7, the module 7 must be electrically powered with a particular flow direction of the electric current according to which face of the module 7 is required to be “hot” and which face is required to be “cold” (the fact that it acts as an electrical conductor for the component 3 being independent of this dedicated power supply).

FIG. 1 thus diagrammatically shows an electrical assembly making it possible to voluntarily electrically power the module 7.

For the other figures, this electrical assembly will not necessarily be shown, with a view to make them easier to read. It is understood, however, that it is indeed present in the various embodiments described in the present application and may be implemented for all embodiments. This supply of the module 7 by the supporting member 2 (either directly or via an additional element and, for example, via a component 3) is applicable for all the other embodiments of the present application such that these explanations will no longer be repeated below.

In the present example, the module 7 associated with the component 3 is thus used to cool it.

The face 8 of the module 7 that is in contact with the second face 6 of the component 3 is thus the cold surface. Optionally, this face 8 is in direct contact with the second face 6 of the component 3.

Thus, in the present example, the current arrives via the supporting member 2 to first reach the face 6 of the module 7. The current then passes through the module 7 and then exits through the face 8 of the module 7, to supply the component 3 before being evacuated by the supporting member 2 and consequently forming a loop.

Powering a thermoelectric module such that one of its faces is hot and the other is cold is well known in the prior art and is not described in greater detail, in this case.

In order to ensure an evacuation of the heat outside the supporting member, the electronic equipment 1 comprises thermal regulation means in contact with the hot face of the module, in this case, the face 9.

The thermal regulation means are or comprise a bus (and, for example, a bus bar) and/or a heat pipe and/or a cover and/or a hood made of thermally conductive material (and, for example, metal or graphene) and/or a thermal drain and/or any other type of heat dissipater and/or heating according to the intended application.

In the present example, the thermal regulation means comprise a thermal drain 10. Optionally, the face 9 is in direct contact with the thermal drain 10. Typically, the face 9 is attached to the thermal drain 10, e.g., by sintering, for example, by sintering based on silver or copper, by cross-linking, for example, a thermally conductive adhesive, or by brazing.

The thermal drain 10 is made of a thermally conductive material, for example, metal, for example, copper, silver, aluminium, gold, palladium, nickel, etc.

In this case, the thermal drain 10 is shaped such that its thickness is much smaller than its other two dimensions.

For example, the thermal drain 10 is either rod-shaped, plate-shaped, etc.

The thermal drain 10 extends, for example, inside of the supporting member 2 so as to open out at one end only to the outside of the supporting member 2. The thermal drain 10 extends, for example, rectilinearly inside of the supporting member 2.

Preferably, the thermal drain 10 is sized to project on either side of the main face of the associated module 7 (the main face 9 in the present case) according to at least one dimension.

According to one option, the module 7 is only partially arranged inside of the supporting member 2. For this purpose, the supporting member 2 comprises a housing 11 opening out at one end at the upper main face 4 of the supporting member 2. In the present example, the housing 11 has an opposite end that is open on the thermal drain 10.

In this case, the module 7 is arranged in the housing 11 such that its top face, the face 8, projects from the top main face 4 of the supporting member 2. On the other hand, its bottom face, face 9, is entirely arranged in the supporting member 2. Typically, between 30% and 95% of the module 7 is arranged inside the supporting member 2, for example, between 50% and 90%.

In the first embodiment thus described, the component 3 is in direct contact with the module 7 that is itself in direct contact with the thermal drain (by the layers of attachment materials as indicated above).

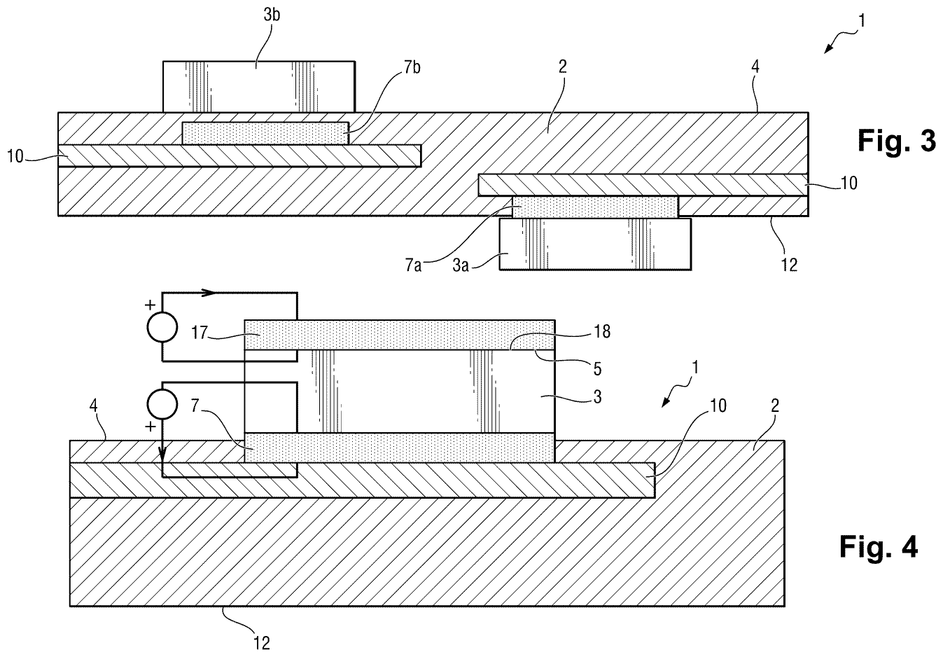

Thus, there is a succession of following layers (apart from the layers of attaching material) along the height of the electronic equipment 1 at the component 3: component 3/module 7/thermal drain 10/supporting member 2. According to a first variant of the first embodiment, the component 3 may be arranged on the lower face 12 of the supporting member 2 and not on its upper face 4 (as can be seen, for example, in FIG. 3).

If the module 7 is attached to the supporting member 1, it will preferably be attached via a material that is at least thermally conductive (and possibly also electrically conductive according to how the module 7 is electrically powered).

According to a second variant of the first embodiment (optionally combinable with the above-mentioned first variant), although, in this case, the module 7 is associated with the component 3 so as to cool the component, the module 7 may be associated with the component 3 so as to heat it. In this case, it will be sufficient to modify the flow direction of the electric current in the electrical power supply of the module 7 so that the face 9 of the module is the cold face and so that the face 8 of the module is the hot face.

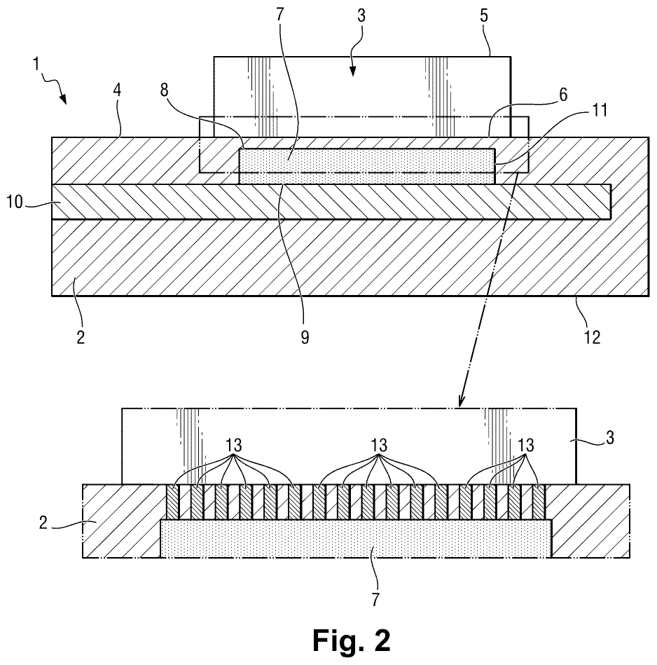

FIG. 2 shows electronic equipment 1 according to a second embodiment, the electronic equipment 1 comprising a supporting member 2. The supporting member 2 is a printed circuit board that carries at least one component 3, in this case, on its upper face 4. In this case, the component 3 has two main faces, a first face 5 facing towards the outside of the supporting member 2 and a second face 6 facing towards the supporting member. The component 3 is connected to the supporting member 2 at its second face 6. The component 3 is associated with a thermoelectric module 7.

Optionally, the component 3 is directly attached to the supporting member 2 Typically, the second face 6 is directly attached to the supporting member, for example, by sintering, for example, by sintering based on silver, copper, etc., by cross-linking, for example, by a thermally conductive adhesive, or by brazing.

The module 7 is shaped as a block comprising two main faces for heat exchange with the outside. The module 7 is shaped such that both of the faces extend parallel to each other. As already stated, the module 7 is electrically powered (for example, via the supporting member 2 and optionally also via the component 3) such that a temperature differential appears between its two main faces. The module 7 thus has a so-called “cold” face and a so-called “hot” face, the hot face (respectively, the cold face) being a first of the two main faces of the module (respectively, the second of the two main faces of the module) according to the flow direction of the electric current in the module.

In the present example, the module 7 is associated with the component 3 so as to cool it. The face 8 that is in contact with the second face 6 of the component 3 is thus, in this case, the cold face.

Optionally, the face 8 is in contact with the second face 6 of the component 3 via at least one thermally conductive link 13. Preferably, the link 13 is also electrically conductive: in this way, the component 3 may be electrically powered and thermally regulated via the same link 13.

This simplifies the electronic equipment 1.

Alternatively, at least two links 13 may connect the component 3 to the module 7, one being thermally conductive and the other being electrically conductive.

For example, the link 13 is a track and/or a pathway. For example, the link 13 is made of metal, for example, copper, silver, aluminium, gold, palladium, nickel, etc.

The link 13 is thus in direct contact, on the one hand, with the component 3 (in this case, the second main face 6 of the component 3) and, on the other hand, in direct contact with the module 7 (in this case, the face 8 of the module 7).

Preferably, the face 8 is in contact with the second face 6 of the component 3 via a multitude of links 13 which thus form, in this case, a “forest” of pathways.

For example, the various links 13 are identical to each other.

The different links 13 extend, for example, identically parallel to one another.

The various links 13 extend, for example, orthogonally to the second main face 6 of the component 3 and to the face 8 of the module 7, while extending between these two faces 6, 8.

In order to ensure an evacuation of the heat outside the supporting member 2, the electronic equipment 1 comprises thermal regulation means in contact with the hot face of the module 7.

The thermal regulation means are or comprise a bus (and, for example, a bus bar) and/or a heat pipe and/or a cover and/or a hood made of thermally conductive material and/or any other type of heat dissipater and/or heating according to the intended application.

In the present example, the thermal regulation means comprise a thermal drain 10. Optionally, the face 9 is in direct contact with the thermal drain 10.

The thermal drain 10 is made of a thermally conductive material, for example, metal, for example, copper, silver, aluminium, gold, palladium, nickel, etc.

In this case, the thermal drain 10 is shaped such that its thickness is much smaller than its other two dimensions. For example, the thermal drain 10 is either rod-shaped, plate-shaped, etc.

The thermal drain 10 extends, for example, inside of the supporting member 2 so as to open out at one end only to the outside of the supporting member 2. The thermal drain 10 extends, for example, rectilinearly inside of the supporting member 2.

Preferably, the thermal drain 10 is sized to project on either side of the main face of the associated module 7 (the main face 9 in the present case) according to at least one dimension.

According to one option, the module 7 is entirely arranged in the supporting member 2. For this purpose, the supporting member 2 comprises a housing 11 that does not open out at the upper main face 4 of the supporting member and of the lower main face 12. In the present example, the housing 11 has one end open to the thermal drain 10 and an opposite end open to the second strip 15.

In the second embodiment thus described, the component 3 is in direct contact with the link 13, that is itself in direct contact with the module 7, that is itself in direct contact with the thermal drain 10.

Thus, there is a succession of the following layers along the height of the electronic equipment 1 at the component 3 (apart from the layers of attaching material): component 3/link 13/module 7/thermal drain 10/supporting member 2.

According to a first variant of the second embodiment, the component 3 may be arranged on the lower face 12 of the supporting member 2 and not on its upper face 4.

According to a second variant of the second embodiment (optionally combinable with the above-mentioned first variant), although, in this case, the module 7 is associated with the component 3 so as to cool the component 3, the module 7 may be associated with the component 3 so as to heat it. In this case, it will be sufficient to modify the flow direction of the electric current in the electrical power supply of the module 7 so that the face 9 of the module is the cold face and so that the face 8 of the module is the hot face.

Naturally, the same supporting member may comprise several module/component pairs. FIG. 3 thus shows a third embodiment in which a first module pair 7a/component 3a according to the first embodiment and a second module pair 7b/component 3b according to the second embodiment are arranged on the same supporting member 2. In the case of FIG. 3, one of the pairs is associated with the upper face 4 of the module 3 and the other of the pairs with its lower face 12, but of course, the two pairs could be associated with the same face of the supporting member 2 (upper face 4 or lower face 12).

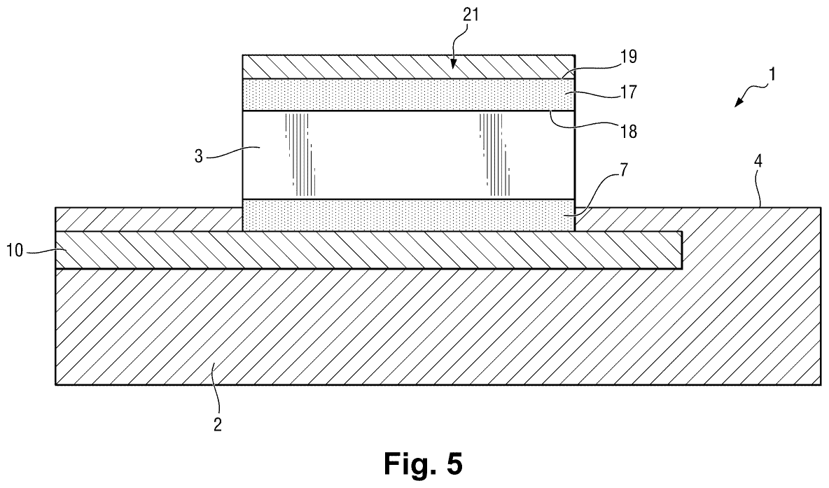

Furthermore, the same component may be associated with several modules such that the component is in contact (directly and/or via a link made of at least thermally conductive material) with at least two thermoelectric modules. FIG. 4 thus shows a fourth embodiment in which the same component 3 is associated with a first module 7 and a second module 17. For example, the first module 7/component 3 pair is the same as that described for the first embodiment (this is of course an option and the first module 7/component 3 pair may be, for example, that described for the second embodiment).

In this case, the second module 17 is identical to the first module 7.

The second module 17 thus has two main faces, namely a face 18 and a face 19.

Optionally, the face 18 of the second module 17 is that which is in contact with the first face 5 of component 3. For example, the face 18 is in direct contact with the first face 5 of the component 3.

Optionally, the second module 17 is configured such that the face 18 is the cold face and the face 19 is the hot face.

As stated above, the first module 7 and the second module 17 are electrically powered in order that each may be used to cool the component 3. The direction of circulation through each of the modules must thus be defined accordingly. The first module 7 may be powered by inserting electrically conductive tracks and/or pathways into the supporting member 2 and/or the component 3 and/or through the second module 17. The second module 17 may be powered by inserting electrically conductive tracks and/or pathways into the supporting member 2 and/or the component 3 and/or through the first module 7.

The component 3 is thus sandwiched between both of the modules 7, 17.

In this case, the second module 17 is entirely outside the supporting member 2. The second module 17 thus evacuates the heat by contact with the environment external to the supporting member 2 (for example, by convection and/or radiation).

In the fourth embodiment thus described, the component 3 is in direct contact with the two modules 7, 17 associated with it.

There is thus the following succession of layers along the height of the electronic equipment 1 at the component (apart from the layers of attaching material): second module 17/component 3/first module 7/heat drain 10/supporting member 2.

According to a first variant of the fourth embodiment, the component 3 may be arranged on the lower face 12 of the supporting member 2 and not on its upper face 4.

According to a second variant of the fourth embodiment (optionally combinable with the above-mentioned first variant), although, in this case, the modules 7, 17 are associated with the component 3 so as to cool the component 3, the modules 7, 17 may be associated with the component 3 so as to heat it. In this case, it will be sufficient to modify the flow direction of the electric current in the electrical power supply of the module 7 and that of the electrical power supply of the module 17 so that the faces 9 and 19 are the cold faces and so that the faces 8 and 18 are the hot faces.

According to a third variant of the fourth embodiment (optionally combinable with the first above-mentioned variant), although, in this case, the two modules 7, 17 are associated with the component 3 so as to cool the component 3, one of the modules 7, 17 may be associated with the component 3 to cool it, and the other of the modules 7, 17 may be associated with the component 3 to heat it. In this case, it will be sufficient to modify the flow direction of the electric current in the electrical power supply of the module 7 and/or the flow direction of the electric current in the electrical power supply of the module 17 so that the faces 9 and 18 are the cold (or hot) faces and so that the faces 8 and 19 are the hot (or cold) faces.

It will thus be possible to operate the module 7 or the module 17 alternatively according to the required purpose. In all cases, it is thus understood that the component 3 comprises a first face associated with a first thermoelectric module 7 and a second face associated with a second thermoelectric module 17 such that the assembly formed by the thermoelectric module 7, the component 3 and the second thermoelectric module 17 forms a stack. In the present example, the assembly formed by the supporting member 2, the thermoelectric module 7, the component 3 and the second thermoelectric module 17 forms a stack.

The term “stack” is understood to mean that the various elements are arranged (preferably successively) on top of each other in a given direction. Preferably, said direction is orthogonal to a plane parallel to at least one of the lower or upper faces of the supporting member 2. Preferably, said direction is vertical when the supporting member 2 is laid flat.

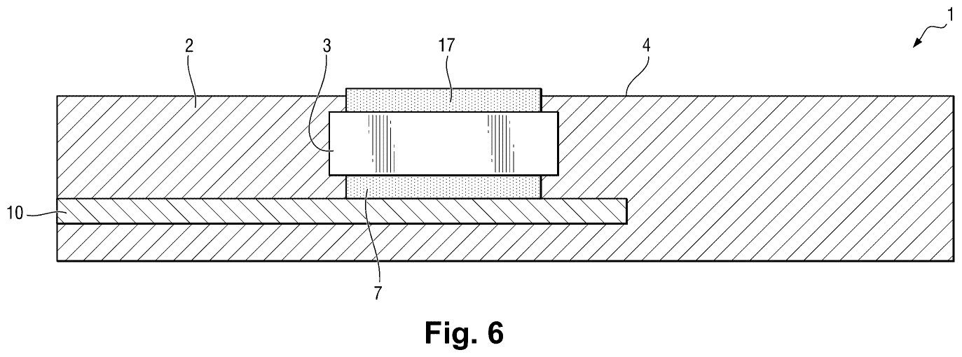

FIG. 5 shows a fifth embodiment that is identical to the fourth embodiment with the difference that the second module 17 does not exchange heat directly with the external environment but exchanges heat with solid thermal regulation means 21 which may or may not be part of the electronic equipment.

Said thermal regulation means are or comprise, for example, a bus (and, for example, a bus bar) and/or a heat pipe and/or a cover and/or a hood made of thermally conductive material (and, for example, metal or graphene) and/or a thermal drain and/or any other type of heat dissipater and/or heating according to the intended application.

For example, at least some of the thermal regulation means 21 are in direct contact with the face 19 of the second module 17 opposite the face 18 attached to the component 3.

The thermal regulation means in direct contact with said face 19 of the second module 17 may have a width and/or a length smaller than that/those of said face. As a variant, the thermal regulation means in direct contact with said face 19 of the second module 17 may have a width and/or a length similar to that/those of said face. As a further variant, the thermal regulation means in direct contact with said face 19 of the second module 17 may have a width and/or a length greater that/those of said face.

In all cases, it is thus understood that the component 3 comprises a first face associated with a first thermoelectric module 7 and a second face associated with a second thermoelectric module 17 such that the assembly formed by the thermoelectric module 7, the component 3 and the second thermoelectric module 17 forms a stack. In the present example, the assembly formed by the supporting member 2, the thermoelectric module 7, the component 3 and the second thermoelectric module 17 forms a stack.

In the present example, the assembly formed by the supporting member 2, the thermoelectric module 7, the component 3 and the second thermoelectric module 17 and the thermal regulation means forms a stack.

The term “stack” is understood to mean that the various elements are arranged (preferably successively) on top of each other in a given direction. Preferably, said direction is orthogonal to a plane parallel to at least one of the lower or upper faces of the supporting member 2. Preferably, said direction is vertical when the supporting member 2 is laid flat.

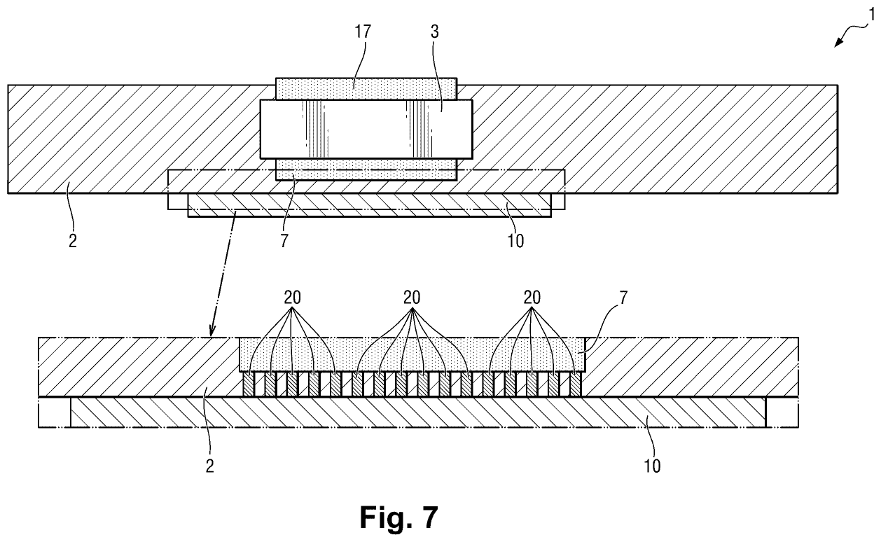

FIG. 6 shows a sixth embodiment that is identical to the fourth embodiment with the difference that the component 3 is not arranged at one of the faces of the supporting member 2 but is entirely arranged inside the supporting member 2. The second module 17 is then arranged only partially inside of the supporting member 2 and no longer entirely outside the supporting member 2.

In this case, the second module 17 is arranged such that its face (opposite that in contact with the component 3) projects from the upper main face 4 of the supporting member 2. On the other hand, its face in contact with the component 3 is entirely arranged in the supporting member 2. Typically, between 30% and 95% of the second module 17 is arranged inside the supporting member 2 and for example between 50 and 90%.

According to a first variant of this sixth embodiment, the second module 17 does not evacuate the heat by contact with the environment external to the supporting member 2 (for example, by convection and/or radiation), but evacuates the heat via thermal regulation means as has been proposed in the fifth embodiment.

According to a second variant of this sixth embodiment, the second module 17 may also be arranged entirely inside the supporting member 2 as in the first module 7. The second module 17 is then associated with thermal regulation means arranged at least partially inside the supporting member 2 as in the first module 7.

In all cases, it is thus understood that the component 3 comprises a first face associated with a first thermoelectric module 7 and a second face associated with a second thermoelectric module 17 such that the assembly formed by the thermoelectric module 7, the component 3 and the second thermoelectric module 17 forms a stack.

The term “stack” is understood to mean that the various elements are arranged (preferably successively) on top of each other in a given direction. Preferably, said direction is orthogonal to a plane parallel to at least one of the lower or upper faces of the supporting member 2. Preferably, said direction is vertical when the supporting member 2 is laid flat.

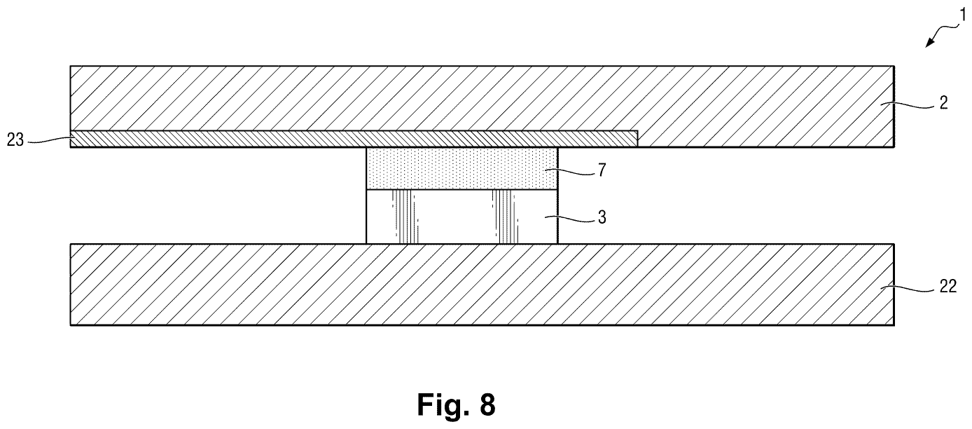

FIG. 7 shows a seventh embodiment that is identical to that of the sixth embodiment except that the first module 7 is not in direct contact with the thermal regulation means but is in contact through at least one thermally conductive link 20.

For example, the link 20 may be the same as the link 13 described for the second embodiment.

Preferably, the module 7 is in direct contact with the thermal regulation means via a multitude of links 20, and preferably via a multitude of links 20, all identical to the links 13 of the second embodiment.

The thermal regulation means associated with the first module 7 are arranged entirely inside the supporting member 2 or else only partially in the supporting member 2 or else entirely outside the supporting member 2.

The thermal regulation means are or comprise, for example, a bus (and, for example, a bus bar) and/or a heat pipe and/or a cover and/or a hood made of thermally conductive material (and, for example, metal or graphene) and/or a thermal drain and/or any other type of heat dissipater and/or heating according to the intended application.

In all cases, it is thus understood that the component 3 comprises a first face associated with a first thermoelectric module 7 and a second face associated with a second thermoelectric module 17 such that the assembly formed by the component 3, the thermoelectric module 7 and the second thermoelectric module 17 forms a stack.

The term “stack” is understood to mean that the various elements are arranged (preferably successively) on top of each other in a given direction. Preferably, said direction is orthogonal to a plane parallel to at least one of the lower or upper faces of the supporting member 2. Preferably, said direction is vertical when the supporting member 2 is laid flat.

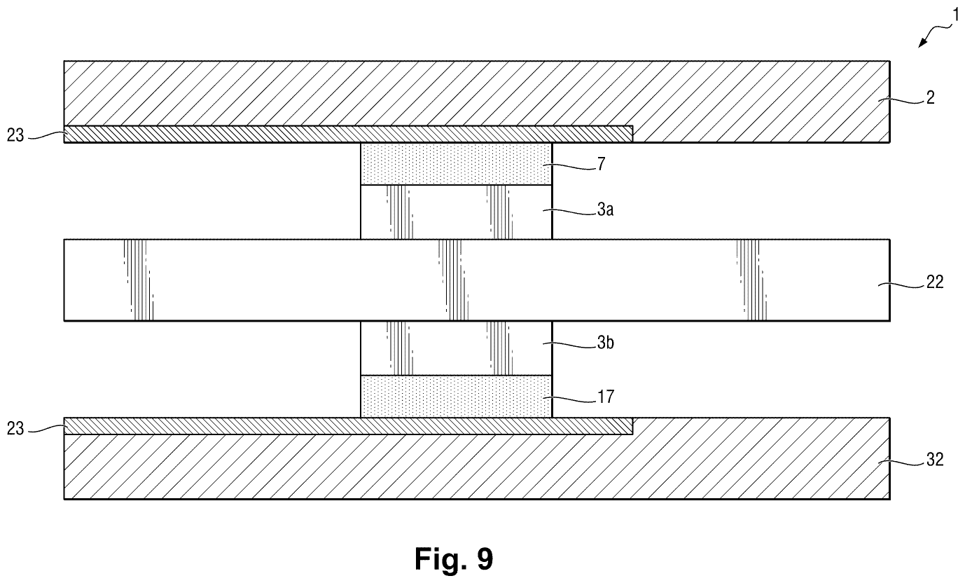

FIG. 8 shows an eighth embodiment that is identical to that of the first embodiment with the difference that the component 3 is not carried by the same supporting member 2 as the module 7.

The electronic equipment 1 thus comprises the supporting member 2 carrying the module 7 as well as an additional supporting member 22 carrying the component 3. The supporting member 22 may be identical to or different from the supporting member 2. The supporting member 22 may thus be a printed circuit board.

Both of the supporting members 2 and 22 are connected to each other at least by the link between the module 7 and the component 3.

In this eighth embodiment thus described, the component 3 is in direct contact with the supporting member 22, on the one hand, and the module 7, on the other hand. As for the module 7, it is logically in direct contact with the component 3, on the one hand, and in direct contact with the supporting member 2, on the other hand.

There is thus the following succession of layers along the height of the electronic equipment 1 at the component (apart from the layers of attaching material): second supporting member 22/component 3/module 7/first supporting member 2.

The module 7 may equally well cool or heat the component 3 according to the direction of the current of its electrical power supply.

The component 3 is thus “sandwiched” between the supporting member 22, on the one hand, and the module 7, on the other hand.

In addition, in this case, it is understood that the thermal regulation is done by the supporting member not carrying the component 3, in this case, the supporting member 2.

For this purpose, the electronic equipment comprises thermal regulation means 21 linked to the module 7.

The thermal regulation means are or comprise, for example, a bus (and, for example, a bus bar) and/or a heat pipe and/or a cover and/or a hood made of thermally conductive material (and, for example, metal or graphene) and/or a thermal drain and/or any other type of heat dissipater and/or heating according to the intended application.

In all cases, it is thus understood that the component 3 comprises a first face associated with a first thermoelectric module 7 and a second face associated with a second supporting member 22 such that the assembly formed by the second supporting member 22, the component 3, the thermoelectric module 7 and the first supporting member 2 forms a stack.

The term “stack” is understood to mean that the various elements are arranged (preferably successively) on top of each other in a given direction. Preferably, said direction is orthogonal to a plane parallel to at least one of the lower or upper faces of the supporting member 2 and/or the supporting member 22. Preferably said direction is vertical when the supporting member 2 is laid flat and/or when the supporting member 22 is laid flat.

FIG. 9 shows a ninth embodiment that is identical to that of the eighth embodiment except that the electronic equipment 1 is larger in number of elements: the electronic equipment 1 thus comprises two components 3a, 3b (instead of one), two modules 7, 17 (instead of one) and three supporting members 2, 22, 32 (instead of two).

The electronic equipment 1 is then, for example, an electronic power module (acting as a rectifier, an inverter, a dimmer, a chopper, etc.). For example, the supporting members 2 and 32 may be printed circuit boards. The supporting member 22 is, for example, composed of one or more metal layers stacked on top of each other. For example, the components 3 are power electronic components. More precisely, the supporting member 22 carries the first component 3a on a first of its main faces and the second component 3b on a second of its main faces. The two components 3a, 3b may be offset from each other or, on the contrary, extend one above the other so as to be superposed (and separated by the supporting member 22). The first component 3a is in direct contact with the supporting member 22, on the one hand, and the module 7, on the other hand. As for the module 7, it is logically in direct contact with the first component 3a, on the one hand, and in direct contact with the supporting member 2, on the other hand.

The second component 3b is in direct contact with the supporting member 22, on the one hand, and the module 17, on the other hand. As for the module 17, it is logically in direct contact with the second component 3b, on the one hand, and in direct contact with the third supporting member 32, on the other hand.

Thus, there is a succession of following layers along the height of the electronic equipment 1 at the components (apart from the layers of attaching material): first supporting member 2/first module 7/first component 3a/second supporting member 22/second component 3b/second module 17/third supporting member 32.

The first module 7 may equally well cool or heat the first component 3a according to the direction of the current of the electrical power supply in question and/or the second module 17 may equally well cool or heat the second component 3b according to the direction of the current of the power supply in question.

The component 3a is thus “sandwiched” between the supporting member 22, on the one hand, and the module 7, on the other hand, and the component 3b is thus “sandwiched” between the supporting member 22, on the one hand, and the module 17, on the other hand.

In addition, in this case, it is understood that the regulation is done by the supporting members not carrying the component, in this case, the supporting member 2 and the supporting member 32.

For this purpose, the electronic equipment comprises thermal regulation means 23 linked to the module 7, on the one hand, and to the module 17, on the other hand.

The thermal regulation means are or comprise, for example, a bus (and, for example, a bus bar) and/or a heat pipe and/or a cover and/or a hood made of thermally conductive material (and, for example, metal or graphene) and/or a thermal drain and/or any other type of heat dissipater and/or heating according to the intended application.

In all cases, it is thus understood that the component 3a has a first face associated with a first thermoelectric module 7 and a second face associated with a second supporting member 22 such that the assembly formed by the first supporting member 2, the thermoelectric module 7, the component 3a and the second supporting member 22 forms a stack.

In all cases, it is thus understood that the component 3b comprises a first face associated with a second thermoelectric module 17 and a second face associated with the second supporting member 22 such that the assembly formed by the second supporting member 22, the component 3b, the thermoelectric module 17 and the third supporting member 32 forms a stack.

The assembly formed by the first supporting member 2, the thermoelectric module 7, the component 3a, the second supporting member 22, the component 3b, the thermoelectric module 17 and the third supporting member 32 forms a stack. The term “stack” is understood to mean that the various elements are arranged (preferably successively) on top of each other in a given direction. Preferably, said direction is orthogonal to a plane parallel to at least one of the lower or upper faces of the supporting member 2 and/or the supporting member 32. Preferably said direction is vertical when the supporting member 2 is laid flat and/or when the supporting member 32 is laid flat.

When the electronic equipment comprises at least one module associated with at least one component of said equipment, the thermal regulation means may be configured to allow the temperature of the component to be monitored and/or this temperature to be regulated. It is thus understood that this is possible regardless of the configuration of the electronic equipment (the various figures showing possible non-limiting configurations in which the electronic equipment comprises at least one component and at least one module).

According to a first option, the thermal regulation means may comprise at least one sensor making it possible to estimate the temperature of the component as well as at least one computing device (of the controller or computer type) communicating with the sensor. As a function of the information transmitted by the sensor, the computing device may adapt the intensity and/or the direction of the current of the electrical power supply of the module associated with the component. In replacement or complementarily, the sensor may measure the temperature difference between the two faces of the module to adapt the intensity and/or the direction of the current of the electrical power supply of the module such that the component is maintained at a setpoint temperature.

According to a second option, f the module opposite that linked to the component is in contact with a Thermal Reference Interface of the thermal regulation means (either directly or via an intermediate element such as an element of the thermal regulation means and, for example, a thermal drain). The Thermal Reference Interface is at a given reference temperature that imposes said reference temperature on the opposite face. The temperature difference between the opposite face of the module and that in contact with the component generates an electric current. By measuring this electric current, it is then possible to estimate the difference between the two faces of the module. This allows action to be taken at the module (by modifying, for example, the intensity and/or the direction of the current of the electrical power supply in question) to modify the temperature difference between its two faces if required.

The Thermal Reference Interface may be brazing, sintering (copper, silver), bonding (based on thermally conductive adhesive), a layer (graphite, graphene, aluminium alloy, silicon alloy), a silicone-based mattress, etc.

With reference to a module/component pair is naturally applicable to another configuration. In particular, when the electronic equipment comprises at least two modules each associated with at least one component of said equipment, the thermal regulation means may be configured to allow monitoring of a temperature difference between the two components and/or regulation of this temperature difference. It is understood that this is possible regardless of the configuration of the electronic equipment (FIG. 3 and FIG. 9 showing possible non-limiting configurations in which the electronic equipment comprises at least two components and at least two modules).

According to a first option, the thermal regulation means may comprise at least one sensor making it possible to estimate the temperature of the 1^{st} component and the temperature of the 2^{nd} component as well as at least one computing device (of the controller or computer type) communicating with the sensor. As function of the information transmitted by the sensor, the computing device may adapt the intensity and/or the direction of the current of the electric power supply of the module associated with the 1^{st} component and/or the module associated with the 2^{nd} component such that the two components are maintained at a setpoint temperature difference (potentially equal to zero). In replacement or complementarily, the sensor may measure the temperature difference between the two faces of the module associated with the 1^{st} component and/or the module associated with the 2^{nd} component to adapt the intensity and/or the direction of the current of the electrical power supply of the module associated with the 1^{st} component and/or the module associated with the 2^{nd} component such that the two components are kept at a setpoint temperature difference (potentially equal to zero).

According to a second option, the face (of at least one of the modules—for example, the first module) opposite that linked to the associated component (in the example, the first module) is in contact with a Thermal Reference Interface of the thermal regulation means (either directly or via an intermediate element such as an element of the thermal regulation means and, for example, a thermal drain). The Thermal Reference Interface may be brazing, sintering (copper, silver), bonding (based on thermally conductive adhesive), a layer (graphite, graphene, aluminium alloy, silicon alloy), a silicone-based mattress, etc.

The Thermal Reference Interface is at a given reference temperature that imposes said reference temperature on the opposite face. The temperature difference between the opposite face of the first module and that in contact with the first component generates an electric current. By measuring this electric current, it is then possible to estimate the difference between the two faces of the first module and thus the temperature of the first component. In this case, by comparing this data with data relating to the temperature of the second component, it is possible to estimate the temperature differential between the two components. It is thus possible to:
take action at the first module (by modifying, for example, the intensity and/or the direction of the current f the electrical power supply in question), and/or
take action at the second module (by modifying, for example, the intensity and/or the direction of the current of the electrical power supply in question),
   such that a difference between the temperature of the first component and the temperature of the second component is maintained at a given setpoint temperature difference (the setpoint temperature difference may be equal to zero).

It is understood, of course, that the explanation provided for a pair or group of two modules/pair or group of two components is applicable to other configurations, for example, a pair or group of at least two modules/pair or group of at least two components.

Naturally, the invention is not limited to the embodiments described, but covers any variant included within the scope of the invention as defined by the claims.

In particular, irrespective of the embodiment, the thermally conductive link may be different from that indicated. For example, said link does not need to be also electrically conductive. If one or more additional electrically conductive links are then necessary to be able to power one or more elements of the electronic equipment, one or more electrical insulation barriers will optionally be arranged in the electronic equipment between the thermally conductive link(s) and the electrically conductive link(s) (the barriers being, for example, based on SiO₂, AlN, etc.).

Irrespective of the embodiment, the same module may be associated with several components such that the module is in contact (directly or by an at least thermally conductive link) with at least two components.

Irrespective of the embodiment, although, in this case, the supporting member is a printed circuit board or a board composed of one or more metal layers, the supporting member may more generally be a substrate.

Irrespective of the embodiment, when at least two elements (module(s), component(s), supporting member(s), etc. ) are said to be “stacked”, this means that they may be in direct contact with each other or be separated by another element (module(s), component(s), supporting member(s), etc.).

Irrespective of the embodiment, when at least one element (module(s), component(s), supporting member(s), etc. ) is said to be “sandwiched” between two other elements (module(s), component(s), supporting member(s), etc.), this means that the three elements in question may be in direct contact with each other or be separated (for at least two of them) by another element (module(s), component(s), supporting member(s), etc.).

Irrespective of the embodiment, the attachment between an element A (module(s), component(s), supporting member(s), etc. ) and an element B (module(s), component(s), supporting member(s), etc.) may be ensured by sintering, cross linking, brazing, etc.

The conductive tracks and/or the pathways and/or any other means making it possible to electrically and/or thermally connect an element A (module(s), component(s), supporting member(s), etc.) and an element B (module(s), component(s), supporting member(s), etc.) may themselves be associated with dedicated thermal regulation means. The thermal regulation means are or comprise, for example, a bus (and, for example, a bus bar) and/or a heat pipe and/or a cover and/or a hood made of thermally conductive material (and, for example, metal or graphene) and/or a thermal drain and/or any other type of heat dissipater and/or heating according to the intended application.

Irrespective of the embodiment:
The module may have a width and/or a length and/or a thickness smaller than that of the associated component.
The module may have a width and/or a length substantially similar to that of the associated component.
For example, the main face of the module in contact (directly or by an at least thermally conductive link) with the face of the component has dimensions similar to those of the component but the thickness of the module is less than that of said component.
For example, the main face of the module in contact (directly or by an at least thermally conductive link) with the face of the component has dimensions smaller to those of the component and the thickness of the module is also less than that of said component.

Irrespective of the embodiment, the component may be arranged entirely outside the supporting member, partially only inside the supporting member or entirely inside the supporting member.

Irrespective of the embodiment, the module may be arranged entirely outside the supporting member, partially only inside the supporting member or entirely inside the supporting member.

Irrespective of the embodiment, at least one of the thermal regulation elements may be arranged entirely outside the supporting member, partially only inside the supporting member or entirely inside the supporting member.

Irrespective of the embodiment, if the equipment comprises several modules, the second module may be arranged entirely outside the supporting member, partially only inside the supporting member or entirely inside the supporting member. The different embodiments may be combined with one another. For example, although the third embodiment proposes to associate with the same supporting member a first module/component pair according to the first embodiment and a second module/component pair according to the second embodiment, the same supporting member may be associated with any first module/component pair described and with any second module/component pair described (the first pair and the second pair may also be identical to each other). Furthermore, the seventh embodiment (in which the module is in contact by an at least thermally conductive link with the thermal regulation means) may be combined with the various other embodiments such that for any embodiment in question, the module may be in direct contact or in contact by an at least thermally conductive link with the thermal regulation means.

Irrespective of the embodiment, the thermal regulation means may be arranged entirely outside the supporting member, partially only inside the supporting member or entirely inside the supporting member. When the thermal regulation means are arranged outside the supporting member, they may be attached to one of the faces of the supporting member or be attached indirectly via the associated module.

Irrespective of the embodiment, the electronic equipment may be a power module, a power module, etc., and/or may be integrated into an electronic system such as a motor, an actuator, an intelligent actuator, an intelligent motor, etc., The electronic system may in turn be optionally integrated into an aircraft and, for example, an electric aircraft.

Irrespective of the embodiment, the component may be of any type, for example, a chip, a surface mounted device (SMD), a package (CMS package or not), a Quad Flat No-leads package (QFN) or a Dual-Flat No-leads package (DFN), a Land Grid Array (LGA), a sensor (such as a gyrometer), a memory, a computing device, an amplification component, etc.

Irrespective of the embodiment, the module may be a semiconductor module, i.e., comprise a p-n junction or any other module making it possible to develop the required thermoelectric effect.

Irrespective of the embodiment, although, in this case, the module is always used by being electrically powered to regulate the temperature of the associated component, the module may also be powered to generate an electric current under the effect of a thermal gradient that will be applied to it via the component (for example, so that the electric current generated by the module is reused supply electric power to another component and/or another module or is used to regulate this thermal gradient or is used to regulate the thermal gradient of another module, etc.). In this case, the thermal regulation means potentially associated with it will complement the role of electrical conductor and/or additional electrical conduction means will be used. Irrespective of the embodiment, one or more elements may be interposed between each thermoelectric module/component pair in question.

Irrespective of the embodiment, the electronic equipment may be shaped to allow temperature regulation of a component and/or a module.

In particular, it is understood that according to the direction of the module's power supply current, the component may be heated or cooled, and that by increasing or decreasing the current intensity, the component may be heated or cooled to a greater or lesser extent. Alternatively, it is also possible to influence not the current but the temperature of the face of the module opposite to that connected to the component requiring thermal regulation.

Irrespective of the embodiment, the electronic equipment may be shaped to allow temperature regulation of a group of at least two components and/or a group of at least two modules and/or a group of at least one component and one module.

It is understood, in particular, that according to the direction of the current of the electrical power supply of at least one of the modules associated with said group, at least one of the elements of said group may be heated or cooled, and that by increasing or decreasing the intensity of the current it is possible to heat or cool said element to a greater or lesser extent such that the temperatures between the various elements within the group are maintained at the same setpoint temperature difference (potentially equal to zero). Alternatively, it is also possible to influence not the current of at least one of the modules associated with the group but to influence the temperature of the face of the module opposite to that connected to the element requiring thermal regulation.

Irrespective of the envisaged embodiment, the electrical power supply of an element A (module, component, etc.) may be provided by an electrically conductive track, by a pathway (by definition, a pathway is electrically conductive), by another element B (module, component, etc.), and also by one of the thermal regulation means of the electronic equipment if said means is also electrically conductive. For example, irrespective of the envisaged embodiment, at least one metal drain may be used to electrically supply the element A while also being used to thermally regulate said element A.

Irrespective of the envisaged embodiment, the electrical power supply of an element A (module, component, etc.) may also make it possible to supply an element B (module, component, etc.) at the same time.

Irrespective of the envisaged embodiment, the thermal regulation means of an element A (module, component, etc.) may also make it possible to regulate an element B (module, component, etc.) at the same time.

1. Electronic equipment comprising:
at least one supporting member;
at least one component;
at least one thermoelectric module associated with the component and shaped as a block comprising two main heat-exchange faces, the at least one thermoelectric module being integrated at least partially into the supporting member such that a first of its two main faces is in contact with at least one of the faces of the at least one component, either directly or via at least one link made of at least thermally conductive material,
wherein the at least one component comprises:
a first face associated with the thermoelectric module; and
a second face associated either with a second thermoelectric module or with a second supporting member, such that an assembly formed by the component, the thermoelectric module and, either the second thermoelectric module or the second supporting member, forms a stack.

2. The equipment according to claim 1, wherein the module is entirely integrated into the supporting member.

3. The equipment according to claim 1, further comprising thermal regulation means associated with the module

4. The equipment according to claim 3, wherein the thermal regulation means are arranged at least partially inside of the supporting member.

5. The equipment according to claim 3, wherein the module is in direct contact with at least one element of the thermal regulation means.

6. The equipment according to claim 3, wherein the thermal regulation means comprise a drain made of a thermally conductive material.

7. The equipment according to claim 3, wherein the thermal regulation means comprise a thermal reference interface, the module being in contact with said thermal reference interface, either directly or via a link made of thermally conductive material.

8. The electronic equipment according to claim 1, wherein the component is a first component, the equipment being configured to allow temperature regulation of a group comprising the first component and at least one second component.

9. The electronic equipment according to claim 8, wherein the module is a first module associated with the first component, the equipment comprising a second module associated with the second component.

10. The electronic equipment according to claim 9, wherein the supporting member is a first supporting member, at least one of the components being carried by a second supporting member of the electronic equipment.

11. The electronic equipment according to claim 9, further comprising a third supporting member carrying the second module.

12. The electronic equipment according to claim 9, wherein the first module implements the Peltier effect and the second module implements the Seebeck effect.

13. The equipment according to claim 1, wherein the equipment is a power module.

14. The electronic system comprising equipment according to claim 1, wherein the electronic system is an aircraft electronic
